(19) United States
(12) Patent Application Publication
(10) Pub. No.: US 2005/0212040 A1
(43) Pub. Date: Sep. 29, 2005

(54) Semiconductor device having gate sidewall structure in silicide process and producing method of the semiconductor device

(75) Inventors: Akira Hokazono, Sagamihara-shi (JP); Makoto Fujiwara, Yokohama-shi (JP)

Correspondence Address: FOLEY AND LARDNER;SUITE 500, 3000 K STREET NW, WASHINGTON, DC, 20007, US

(73) Assignee: KABUSHIKI KAISHA TOSHIBA

(21) Appl. No.: 10/947,405

(22) Filed: Sep. 23, 2004

(30) Foreign Application Priority Data
Mar. 25, 2004 (JP) 2004-089478

(51) Int. Cl. H01L 21/336

(52) U.S. Cl. 257/333

(57) ABSTRACT

A gate insulation film is formed on a semiconductor substrate. A gate electrode is formed on the gate insulation film. A silicide film is formed on the gate electrode. First gate sidewall films are formed on side surfaces of the gate electrode. Second gate sidewall films are formed on the first gate sidewall films on the side surfaces of the gate electrode. First sidewall films are formed on side surfaces of the silicide film on the gate electrode. A source region and a drain region are formed on the semiconductor substrate so as to sandwich a channel region formed under the gate insulation film. Second sidewall films are formed on end portions of the first and second gate sidewall films formed on the source region and the drain region.

### CROSS-REFERENCE TO RELATED APPLICATIONS

This application is based upon and claims the benefit of priority from prior Japanese Patent Application No. 2004-089478, filed Mar. 25, 2004, the entire contents of which are incorporated herein by reference.

### BACKGROUND OF THE INVENTION

1. Field of the Invention

This invention relates to a semiconductor device and a producing method of the semiconductor device and, more particularly, to a gate sidewall structure of an MIS field effect transistor (MIS FET) in a silicide process.

2. Description of the Related Art

Recently, a silicidation technique to form a silicide film on a gate electrode and a source/drain region of a MIS FET has been an indispensable process for reduction of parasitic resistance (see, for example, Jpn. Pat. Appln. KOKAI Publication No. 2001-111044, FIG. 16 and the like). However, some problems relating to the silicide process have been found in accordance with scaling of the MIS FET.

FIGS. 1 and 2 are cross-sectional views showing a semiconductor having the problems about the silicide process. If gate sidewall films 51 are formed on side surfaces of each of gate electrodes 50A and 50B, the gate sidewall films 51 slightly fall down from a top surface of the gate electrode 50A or 50B. Side surfaces of a top portion of the gate electrode 50A or 50B are thereby exposed as shown in FIGS. 1 and 2. If the top portion of the gate electrode in this state is silicified, silicidation proceeds from the exposed side surfaces of the top portion of the gate electrode 50A or 50B.

If the gate length of the gate electrode 50A is great, influence of silicidation which proceeds from the side surfaces of the top portion of the gate electrode 50A, as given to the gate electrode 50A, is small as shown in FIG. 1. In other words, a silicide film 52A cannot be formed to reach a deep position of the gate electrode 50A. If scaling of the gate length proceeds and the gate length becomes small as shown in FIG. 2, however, the influence of silicidation which proceeds from the side surfaces of the top portion of the gate electrode SOB, as given to the gate electrode SOB, can hardly be neglected. As the gate length is smaller, a silicide film 52B is formed to be thicker (reverse fine-line effect) and may reach a gate insulation film 53 in a worst case. For this reason, sheet resistance of the silicide film may be irregular in accordance with the gate length, reliability of the gate insulation film may be damaged or a threshold value may be shifted in accordance with variation in a work function of a gate electrode material. In addition, an amount of etching (pretreatment of silicide) to remove a natural oxide film, which is performed prior to formation of the silicide film, is constant while scaling of the gate length, the height of the gate electrode and the width of the gate sidewall is performed. Therefore the rate of expose of the side surfaces of the gate electrode to the height of the gate electrode becomes greater. As a result, silicidation proceeding on the side surfaces of the gate electrode needs to be restricted.

FIG. 3 illustrates a cross-sectional view showing details of conventional structures of a gate electrode and gate sidewall films to explain the problem to be solved by the present invention. In the structure of FIG. 3, there is a problem that the gate sidewall films composed of a silicon nitride film are etched by removal of a native oxide film which is performed prior to formation of a silicide film, side surfaces of a top portion of the gate electrode are exposed and silicidation proceeds from the side surfaces of the top portion of the gate electrode (A of FIG. 3). To maintain the reliability of transistor, the silicon oxide films need to be formed on side surfaces of a lower portion of the gate electrode (B of FIG. 3). As an end portion of the gate sidewall film which is in contact with the semiconductor substrate is etched by removal of a native oxide film as performed prior to formation of a silicide film (C of FIG. 3), the gate sidewall film is lift off at the scaling of the width of the gate sidewall film or the gate and the source/drain are shorted due to application of an elevated source/drain process.

### BRIEF SUMMARY OF THE INVENTION

According to an aspect of the present invention, there is provided a semiconductor device. The semiconductor device comprises a gate insulation film formed on a semiconductor substrate, a gate electrode formed on the gate insulation film, a silicide film formed on the gate electrode, first gate sidewall films formed on side surfaces of the gate electrode, second gate sidewall films formed on the first gate sidewall films on the side surfaces of the gate electrode, first sidewall films formed on side surfaces of the silicide film on the gate electrode, a source region and a drain region formed on the semiconductor substrate so as to sandwich a channel region formed under the gate insulation film, and second sidewall films formed on end portions of the first and second gate sidewall films formed on the source region and the drain region.

According to another aspect of the present invention, there is provided a method of producing a semiconductor device. The method comprises forming a gate insulation film on a semiconductor substrate, forming a gate electrode on the gate insulation film, forming first gate sidewall films on side surfaces of the gate electrode and on the semiconductor substrate, forming second gate sidewall films on the first gate sidewall films, forming third gate sidewall films on the second gate sidewall films, forming first sidewall films on side surfaces of a top portion of the gate electrode, and on end portions of the first and second gate sidewall films on the semiconductor substrate, forming a source region and a drain region on the semiconductor substrate on both sides of the third gate sidewall films by ion implantation using the third gate sidewall films as mask members, removing a native oxide film on the gate electrode, the source region and the drain region, forming a metal film on the gate electrode, the source region and the drain region, and performing heat treatment on the gate electrode, the source region and the drain region, and the metal film, to form metal silicide films on the gate electrode, the source region and the drain region.

### BRIEF DESCRIPTION OF THE SEVERAL VIEWS OF THE DRAWING

FIG. 1 illustrates cross-sectional views of a semiconductor device showing a problem about a conventional silicide process;

FIG. 2 illustrates cross-sectional views of another semiconductor device showing the problem about the conventional silicide process;

FIG. 3 illustrates a cross-sectional view showing details of conventional structures of a gate electrode and gate sidewall films;

FIG. 4 illustrates a cross-sectional view of a MOS field effect transistor (MOSFET) according to a first embodiment of the present invention;

FIG. 5 illustrates a cross-sectional view of the MOSFET according to the first embodiment in a first step of a producing method of the MOSFET;

FIG. 6 illustrates a cross-sectional view of the MOSFET according to the first embodiment in a second step of the producing method of the MOSFET;

FIG. 7 illustrates a cross-sectional view of the MOSFET according to the first embodiment in a third step of the producing method of the MOSFET;

FIG. 8 illustrates a cross-sectional view of the MOSFET according to the first embodiment in a fourth step of the producing method of the MOSFET;

FIG. 9 illustrates a cross-sectional view of the MOSFET according to the first embodiment;

FIG. 10 illustrates a cross-sectional view of a MOSFET according to a second embodiment of the present invention;

FIG. 11 illustrates a cross-sectional view of the MOSFET according to the second embodiment in a first step of a producing method of the MOSFET;

FIG. 12 illustrates a cross-sectional view of the MOSFET according to the second embodiment in a second step of the producing method of the MOSFET;

FIG. 13 illustrates a cross-sectional view of the MOSFET according to the second embodiment in a third step of the producing method of the MOSFET;

FIG. 14 illustrates a cross-sectional view of the MOSFET according to the second embodiment in a fourth step of the producing method of the MOSFET;

FIG. 15 illustrates a cross-sectional view of the MOSFET according to the second embodiment;

FIG. 16 illustrates a cross-sectional view of a MOSFET according to a third embodiment of the present invention;

FIG. 17 illustrates a cross-sectional view of the MOSFET according to the third embodiment in a first step of a producing method of the MOSFET;

FIG. 18 illustrates a cross-sectional view of the MOSFET according to the third embodiment in a second step of the producing method of the MOSFET;

FIG. 19 illustrates a cross-sectional view of the MOSFET according to the third embodiment in a third step of the producing method of the MOSFET;

FIG. 20 illustrates a cross-sectional view of the MOSFET according to the third embodiment in a fourth step of the producing method of the MOSFET; and

FIG. 21 illustrates a cross-sectional view of the MOSFET according to the third embodiment.

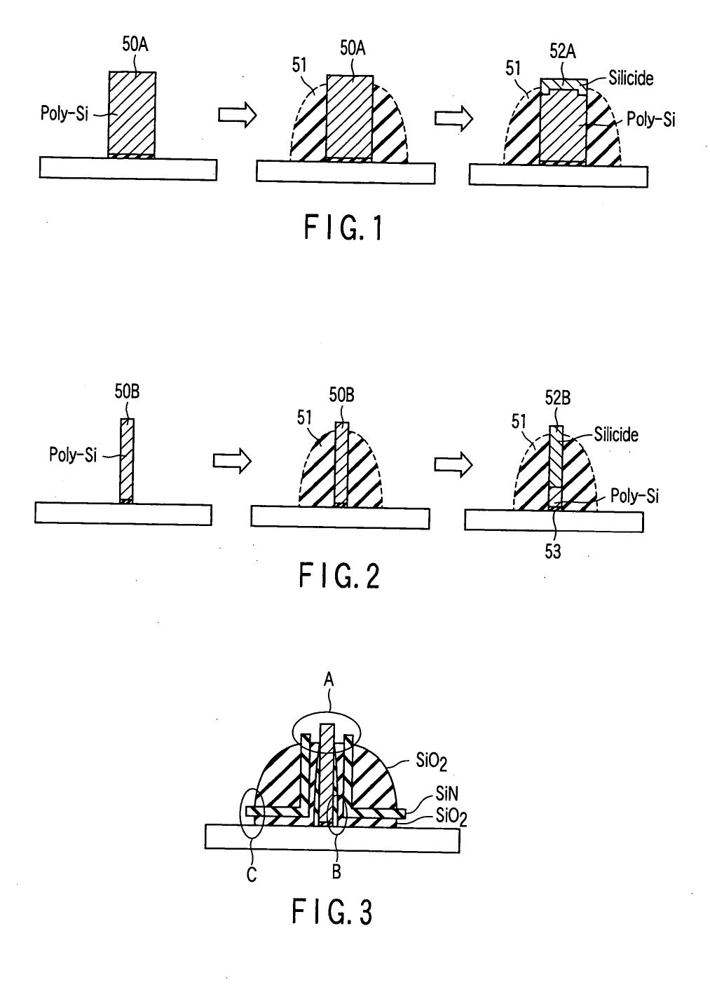

### DETAILED DESCRIPTION OF THE INVENTION

Embodiments of the present invention will be explained below with reference to the accompanying drawings. Like elements are denoted throughout the drawings by like or similar reference numbers.

### First Embodiment

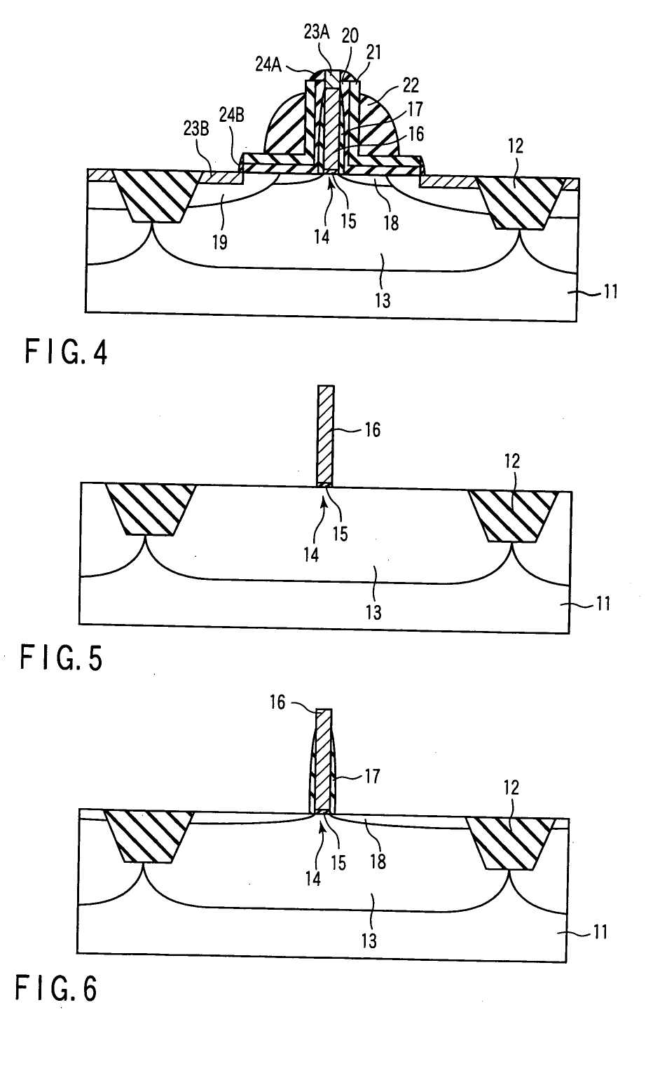

First, a semiconductor device including a MOS field effect transistor (MOSFET) according to a first embodiment of the present invention will be explained. FIG. 4 illustrates a cross-sectional view of the MOSFET according to the first embodiment.

Element isolation films 12 are formed on a p-type silicon semiconductor substrate (or an n-type silicon semiconductor substrate) 11. A well region 13 and a channel region 14 are formed on the semiconductor substrate 11 of an active element portion surrounded by the element isolation films 12. A gate insulation film 15 is formed on the semiconductor substrate (channel region) 11 of the active element portion. A gate electrode 16 is formed on the gate insulation film 15.

Offset spacers 17 composed of silicon oxide films are formed on side surfaces of the gate electrode 16. Shallow diffusion layers 18 are formed on the surface region of the semiconductor substrate 11 so as to sandwich the channel region 14. Contact junctions 19 serving as a source region and a drain region are further formed on the surface region of the semiconductor substrate 11 so as to sandwich the shallow diffusion layers 18.

First gate sidewall films 20 composed of silicon oxide films are formed on the offset spacers 17 on the side surfaces of the gate electrode 16. Second gate sidewall films 21 composed of silicon nitride films are formed on the first gate sidewall films 20. Third gate sidewall films 22 composed of silicon oxide films are formed on the second gate sidewall films 21. Each of the first gate sidewall films 20 and the second gate sidewall films 21 is shaped in L letter and an end thereof extends to the top surface of the contact junction 19.

A silicide film 23A is formed on a top surface of the gate electrode 16 and silicide films 23B are formed on the contact junctions 19. Sidewall films 24A composed of silicon nitride films are formed on side surfaces of the silicide film 23A. Moreover, sidewall films 24B composed of silicon nitride films are formed on side surfaces of the first gate sidewall films 20 and the second gate sidewall films 21 on the contact junctions 19. The sidewall films 24A and 24B are formed in the same producing process.

In the semiconductor device having the above-described structure, for example, as the silicon nitride films formed of a different material from the silicon oxide films are formed on the side surfaces of the top portion of the gate electrode, the side surfaces of the top portion of the gate electrode can be prevented from being exposed during a preprocessing performed prior to formation of the silicide films. To describe detail, as the sidewall films (silicon nitride films) 24A different from the silicon oxide films are formed on the side surfaces of the silicide film 23A on the gate electrode 16, the side surfaces of the top portion of the gate electrode can be prevented from being exposed during removal of a native oxide film which is performed prior to formation of the silicide films. Thus, the gate electrode can be prevented from being silicified from the side surfaces of the top portion of the gate electrode and the silicide films can be prevented from being formed from the top surface of the gate electrode to deep positions.

In addition, as the first gate sidewall films (silicon oxide films) 20 are formed on the side surfaces of the lower portion of the gate electrode 16, a problem of decrease in reliability of the transistor does not arise. The offset spacers 17 are formed on the side surfaces of the lower portion of the gate electrode 16. However, as the offset spacers 17 are thin, reliability of the transistor cannot be maintained with the offset spacers alone.

Moreover, the sidewall films (silicon nitride films) 24B are formed on the side surfaces (end portions) of the first gate sidewall films 20 and second gate sidewall films 21 which are in contact with the semiconductor substrate 11. Thus, the first gate sidewall films (silicon oxide films) 20 can be prevented from being etched during removal of the native oxide film which is performed prior to formation of the silicide films. For this reason, the second gate sidewall films 21 and the third gate sidewall films 22 can be prevented from being lift off and scaling of the third gate sidewall films 22 can be performed. Even in a case of applying the elevated source/drain process, the gate and the source/drain can be prevented from being shorted by a silicon layer, a silicon germanium layer or the like which is to be formed later.

Next, a method of producing the MOSFET according to the first embodiment will be explained. FIG. 5 to FIG. 9 illustrate steps in the method of producing the MOSFET.

As shown in FIG. 5, the element isolation films 12 having a depth of 200 to 350 nm are formed on the p-type silicon semiconductor substrate (or n-type silicon semiconductor substrate) 11 by buried element isolation method. A silicon oxide film having a thickness of 20 nm or smaller is formed on the p-type silicon semiconductor substrate 11 of the active element portion surrounded by the element isolation films 12. After that, impurity is introduced by ion implantation and activation rapid thermal annealing (RTA) is performed to form the well region 13 and the channel region 14. The following are the conditions for the ion implantation. For example, if an n-type well region is formed, phosphorus (P) is implanted at an acceleration voltage of 500 KeV and a dose of 3.0×10¹³ cm⁻², and boron (B) is implanted at an acceleration voltage of 10 KeV and a dose of 1.5×10¹³ cm⁻² for formation of the channel region. If a p-type well region is formed, boron is implanted at an acceleration voltage of 260 KeV and a dose of 2.0×10¹³ cm⁻², and arsenic (As) is implanted at an acceleration voltage of 100 KeV and a dose of 1.5×10¹³ cm⁻² for formation of the channel region.

Next, the gate insulation film 15 composed of a silicon oxide film is formed in the channel region 14 of the well region 13 by thermal oxidation or LPCVD, as shown in FIG. 15, such that the gate insulation film 15 is approximately 1 to 6 nm thick. A polysilicon film or a polysilicon germanium film being approximately 50 to 200 nm thick is deposited on the gate insulation film 15. A resist mask pattern is formed by optical lithography, X-ray lithography or electron-beam lithography and the polysilicon film or polysilicon germanium film is etched by reactive ion etching (RIE) to form the gate electrode 16. The gate insulation film 15 is formed of a silicon oxide film (SiO₂), but may be formed of, for example, SiON, SiN or a highly dielectric film such as Ta₂O₅. The gate electrode 16 is formed of a polysilicon film or a polysilicon germanium film, but may be formed of tungsten (W) with a metal gate structure using tungsten nitride (WN) as a barrier metal.

Next, a silicon oxide film (SiO₂) being 1 to 6 nm thick is formed in the structure shown in FIG. 5, by thermal oxidation as performed as post-oxidation. Moreover, a silicon oxide film is deposited by LPCVD. Etch back is performed by RIE and the offset spacers 17 are thereby formed on the side surfaces of the gate electrode 16 as shown in FIG. 6. Subsequently, impurities are introduced onto the semiconductor substrate 11 on both sides of the offset spacers 17 by ion implantation and RTA is performed to form the shallow diffusion layers 18, such that the channel region 14 is sandwiched between the shallow diffusion layers 18. The following are the conditions for the ion implantation. For example, if an n-type well region is formed, arsenic (As) is implanted at an acceleration voltage of 1 to 5 KeV and a dose of 5.0×10¹⁴ cm⁻². If a p-type well region is formed, BF₂ is implanted at an acceleration voltage of 1 to 3 KeV and a dose of 5.0×10¹⁴ to 1.5×10¹⁵ m⁻², or boron (B) is implanted.

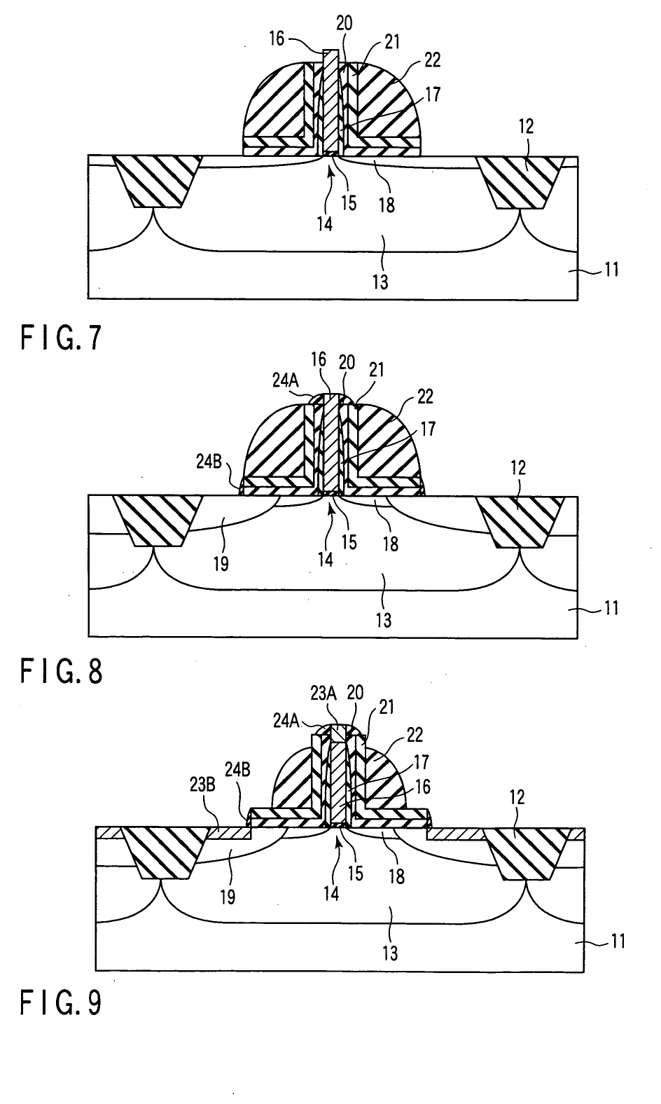

Next, a silicon oxide film, a silicon nitride film and a silicon oxide film are deposited in order on the structure shown in FIG. 6, i.e. on the offset spacers 17 on the side surfaces of the gate electrode 16. Subsequently, the silicon oxide film, the silicon nitride film and the silicon oxide film are subjected to etch back by RIE. The first gate sidewall films 20, the second gate sidewall films 21 and the third gate sidewall films 22 are thereby formed as shown in FIG. 7. At this time, overetching is slightly performed to certainly perform patterning of these sidewall insulation films. For this reason, the side surfaces of the top portion of the gate electrode 16 are exposed.

Subsequently, a silicon nitride film is deposited on the structure shown in FIG. 7. After that, etch back is performed by RIE, such that the sidewall films 24A are formed on the side surfaces of the top portion of the gate electrode 16 and that the sidewall films 24B are formed on the side surfaces (end portions) of the first gate sidewall films 20 and the second gate sidewall films 21 on the semiconductor substrate 11, as shown in FIG. 8. At this time, the sidewall films 24A and 24B prevent the L-shaped first gate sidewall films 20 formed of a silicon oxide film from being exposed. Impurities are introduced onto the semiconductor substrate 11 on both sides of the third gate sidewall films 22 by ion implantation and RTA is further performed to form the contact junctions 19 which are to serve as the source region and the drain region. The contact junctions 19 are formed after formation of the sidewall films 24A and 24B, but may be formed before formation of the sidewall films 24A and 24B.

Next, after diluted hydrofluoric acid processing is performed to remove the native oxide film, in the structure shown in FIG. 8, the silicide film 23A is formed on the gate electrode 16 and the silicide films 23B are formed on the contact junctions 19 (salicide). The silicide films 23A and 23B are formed of, for example, silicides of Ni, Ti, Co, Pb or the like. The salicide of forming nickel silicide films is explained here. First, a nickel film is deposited on the gate electrode 16 and the contact junctions 19 by spattering. Then, RTA is performed at a temperature of 400 to 500° C. to silicify the nickel film. An unreacted portion of the nickel film is removed with a mixture solution of sulfuric acid and hydrogen peroxide solution, and nickel silicide films 23A and 23B are formed on the gate electrode 16 and the contact junctions 19 as shown in FIG. 9. A titanium nitride (TiN) film may be deposited after deposition of the nickel film. After performing RTA at a low temperature of 250 to 400° C., a process (two-step annealing) of etching the nickel film with a mixture solution of sulfuric acid and hydrogen peroxide solution and performing RTA again at 400 to 500° C. to decrease the sheet resistance may be applied. A process of silicon selective epitaxial growth or selective growth of silicon germanium may be applied before and after formation of the contact junctions 19.

After that, a CMOS device is produced in the following manners though not shown. A film having a higher etching selective ratio than an interlayer insulation film which is to be formed later is formed on the silicide films 23B, in the structure shown in FIG. 9. The purpose of forming a film having a higher etching selective ratio on the silicide films 23B is to prevent the silicide films 23B on the semiconductor substrate 11 from being etched and the junction leakage from being deteriorated, by formation of a contact hole using RIE which is to be described later.

Subsequently, an interlayer insulation film of, for example, TEOS, BPSG, or SiN is deposited and a surface of the interlayer insulation film is planarized by performing CMP. After a resist mask pattern is formed for formation of a contact hole by photolithography, a contact hole is formed by RIE. After that, titanium (Ti) and titanium nitride (TiN) are deposited as barrier metals, tungsten (W) is subjected to selective growth or formed entirely, and CMP is performed. Finally, a metal film which is to be a wiring layer is deposited and patterned. The wiring layer connected to the contact hole is thereby formed on the interlayer insulation film. Thus, the CMOS device is formed.

As the sidewall films (silicon nitride films) 24A different from silicon oxide films are formed on the side surfaces of the top portion of the gate electrode 16 in the above-described producing steps, the side surfaces of the top portion of the gate electrode 16 can be prevented from being exposed in the step of removing a native oxide film which is performed prior to formation of the silicide films. Thus, the nickel film is not formed on the side surfaces of the top portion of the gate electrode 16 in the step of forming the silicide films. For this reason, silicidation of the gate electrode 16 from the side surfaces of the top portion of the gate electrode 16 can be restricted or, in other words, formation of a nickel silicide film from the side surfaces of the gate electrode 16 can be restricted. The formation of the silicide film from the top surface of the gate electrode 16 to a deep position can be therefore prevented. As a result, as the first gate sidewall films (silicon oxide films) 20 are formed on the side surfaces of the lower portion of the gate electrode 16, a problem of decrease in reliability of transistor does not arise.

As the sidewall films (silicon nitride films) 24B are formed on the side surfaces (end portions) of the first gate sidewall films 20 and second gate sidewall films 21, which are in contact with the semiconductor substrate 11, the first gate sidewall films (silicon oxide films) 20 can be prevented from being etched in the step of removing a native oxide film which is performed prior to formation of the silicide films. Thus, the second gate sidewall films 21 and the third gate sidewall films 22 can be prevented from being lift off. Even in a case where the elevated source/drain process is applied, the gate and the source/drain can be prevented from being shorted by the formed silicon layer or silicon germanium layer.

### Second Embodiment

Next, a semiconductor device including a MOS field effect transistor (MOSFET) according to a second embodiment of the present invention will be explained. Elements of the second embodiment similar to those of the first embodiment are denoted by like or similar reference numbers.

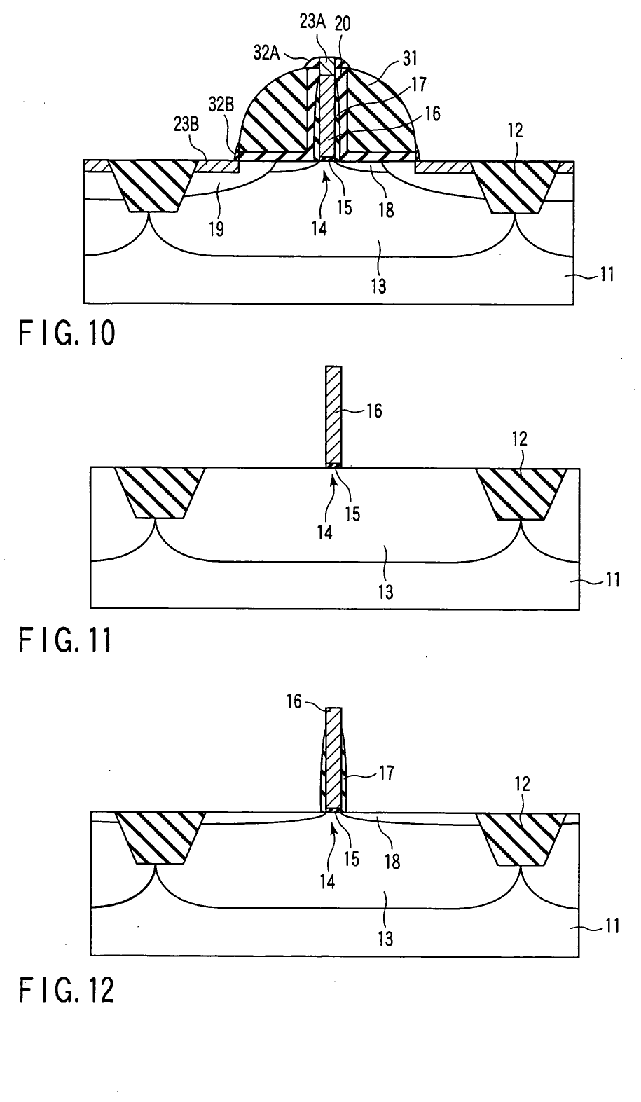

FIG. 10 illustrates a cross-sectional view of the MOSFET according to the second embodiment. Element isolation films 12 are formed on a p-type silicon semiconductor substrate (or an n-type silicon semiconductor substrate) 11. A well region 13 and a channel region 14 are formed on the semiconductor substrate 11 of an active element portion surrounded by the element isolation films 12. A gate insulation film 15 is formed on the semiconductor substrate (channel region) 11 of the active element portion. A gate electrode 16 is formed on the gate insulation film 15.

Offset spacers 17 composed of silicon oxide films are formed on side surfaces of the gate electrode 16. Shallow diffusion layers 18 are formed on the surface region of the semiconductor substrate 11 so as to sandwich the channel region 14. Contact junctions 19 serving as a source region and a drain region are further formed on the surface region of the semiconductor substrate 11 so as to sandwich the shallow diffusion layers 18.

First gate sidewall films 20 composed of silicon oxide films are formed on the offset spacers 17 on the side surfaces of the gate electrode 16. Second gate sidewall films 31 composed of silicon nitride films are formed on the first gate sidewall films 20. Each of the first gate sidewall films 20 is shaped in L letter and an end thereof extends to the top surface of the contact junction 19.

A silicide film 23A is formed on a top surface of the gate electrode 16 and silicide films 23B are formed on the contact junctions 19. Sidewall films 32A composed of silicon nitride films are formed on side surfaces of the silicide film 23A located on the top surface of the gate electrode 16. Moreover, sidewall films 32B composed of silicon nitride films are formed on side surfaces of the first gate sidewall films 20 on the contact junctions 19. The sidewall films 32A and 32B are formed in the same producing process.

In the semiconductor device having the above-described structure, for example, as the silicon nitride films formed of a different material from the silicon oxide films are formed on the side surfaces of the top portion of the gate electrode, the side surfaces of the top portion of the gate electrode can be prevented from being exposed during a preprocessing performed prior to formation of the silicide films. To describe detail, as the sidewall films (silicon nitride films) 32A different from the silicon oxide films are formed on the side surfaces of the silicide film 23A on the gate electrode 16, the side surfaces of the top portion of the gate electrode can be prevented from being exposed during removal of a native oxide film which is performed prior to formation of the silicide films. Thus, the gate electrode can be prevented from being silicified from the side surfaces of the top portion of the gate electrode and the silicide films can be prevented from being formed from the top surface of the gate electrode to deep positions.

In addition, as the first gate sidewall films (silicon oxide films) 20 are formed on the side surfaces of the lower portion of the gate electrode 16, a problem of decrease in reliability of the transistor does not arise. The offset spacers 17 are formed on the side surfaces of the lower portion of the gate electrode 16. However, as the offset spacers 17 are thin, reliability of the transistor cannot be maintained with the offset spacers alone. Moreover, the sidewall films (silicon nitride films) 32B are formed on the side surfaces (end portions) of the first gate sidewall films 20 which are in contact with the semiconductor substrate 11. Thus, the first gate sidewall films (silicon oxide films) 20 can be prevented from being etched during removal of the native oxide film which is performed prior to formation of the silicide films. For this reason, the second gate sidewall films 31 can be prevented from being lift off and scaling of the second gate sidewall films 31 can be therefore performed. Even in a case where the elevated source/drain process is applied, the gate and the source/drain can be prevented from being shorted by a silicon layer, a silicon germanium layer or the like which is to be formed later.

Next, a method of producing the MOSFET according to the second embodiment will be explained. FIG. 11 to FIG. 15 illustrate steps in the method of producing the MOSFET.

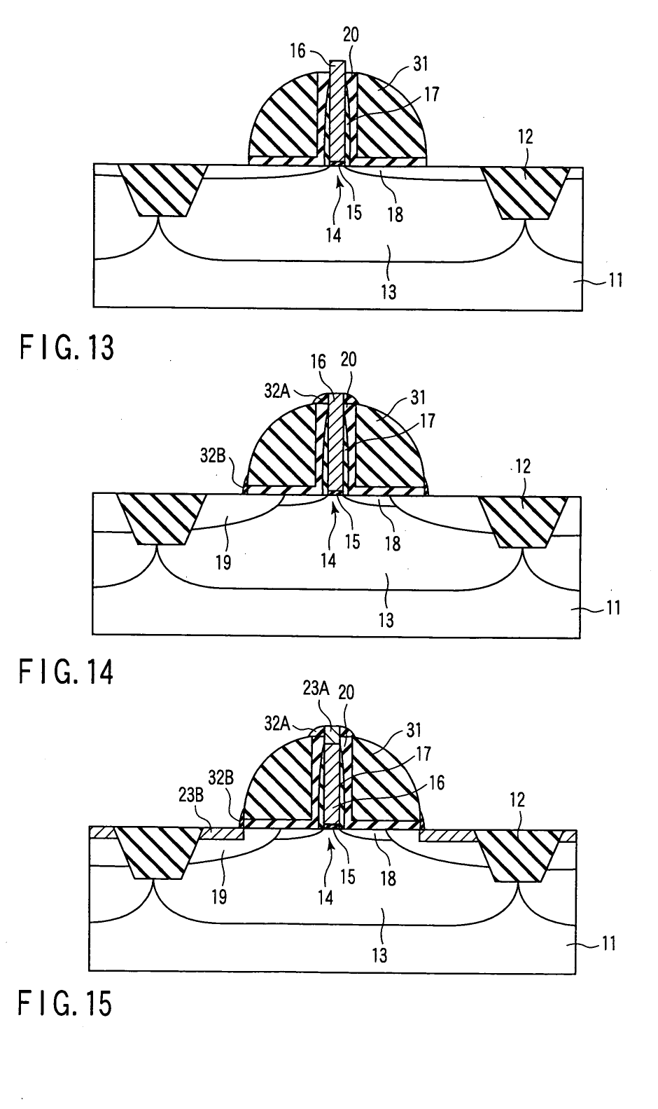

The steps shown in FIGS. 11 and 12 are the same as the steps of the first embodiment shown in FIGS. 5 and 6. Next, a silicon oxide film and a silicon nitride film are deposited in order on the structure shown in FIG. 12, i.e. on the offset spacers 17 on the side surfaces of the gate electrode 16. Subsequently, the silicon oxide film and the silicon nitride film are subjected to etch back by RIE, such that the first gate sidewall films 20 and the second gate sidewall films 31 are formed as shown in FIG. 13. The second gate sidewall films 31 are therefore arranged on the L-shaped first gate sidewall films 20. At this time, overetching is slightly performed to certainly perform patterning of these sidewall insulation films. For this reason, the side surfaces of the top portion of the gate electrode 16 are exposed.

Subsequently, a silicon nitride film is deposited on the structure shown in FIG. 13. After that, etch back is performed by RIE, such that the sidewall films 32A are formed on the side surfaces of the top portion of the gate electrode 16 and that the sidewall films 32B are formed on the side surfaces (end portions) of the first gate sidewall films 20 on the semiconductor substrate 11, as shown in FIG. 14. At this time, the sidewall films 32A and 32B prevent the L-shaped first gate sidewall films 20 formed of a silicon oxide film from being exposed. Impurities are introduced onto the semiconductor substrate 11 on both sides of the second gate sidewall films 31 by ion implantation and RTA is further performed to form the contact junctions 19 which are to serve as the source region and the drain region. The contact junctions 19 are formed after formation of the sidewall films 32A and 32B, but may be formed before formation of the sidewall films 32A and 32B.

Next, after diluted hydrofluoric acid processing is performed to remove the native oxide film, in the structure shown in FIG. 14, the silicide film 23A is formed on the gate electrode 16 and the silicide films 23B are formed on the contact junctions 19 (salicide). The silicide films 23A and 23B are formed of, for example, silicides of Ni, Ti, Co, Pb or the like. The salicide of forming nickel silicide films is explained here. First, a nickel film is deposited on the gate electrode 16 and the contact junctions 19 by spattering. Then, RTA is performed at a temperature of 400 to 500° C. to silicify the nickel film. After that, an unreacted portion of the nickel film is removed with a mixture solution of sulfuric acid and hydrogen peroxide solution, and nickel silicide films 23A and 23B are formed on the gate electrode 16 and the contact junctions 19 as shown in FIG. 15. The other producing steps are the same as those of the first embodiment.

The sidewall films (silicon nitride films) 32A different from silicon oxide films are formed on the side surfaces of the top portion of the gate electrode 16, as shown in FIG. 14, in the above-described producing steps. Thus, the side surfaces of the top portion of the gate electrode 16 can be prevented from being exposed in the step of removing a native oxide film which is performed prior to formation of the silicide films. The nickel film is not formed on the side surfaces of the top portion of the gate electrode 16 in the step of forming the silicide films. For this reason, silicidation of the gate electrode 16 from the side surfaces of the top portion of the gate electrode 16 can be restricted or, in other words, formation of a nickel silicide film from the side surfaces of the gate electrode 16 can be restricted. The formation of the silicide film from the top surface of the gate electrode 16 to a deep position can be therefore prevented. As the first gate sidewall films (silicon oxide films) 20 are formed on the side surfaces of the lower portion of the gate electrode 16, a problem of decrease in reliability of transistor does not arise.

Furthermore, as the sidewall films (silicon nitride films)-32B are formed on the side surfaces (end portions) of the first gate sidewall films 20 which are in contact with the semiconductor substrate 11, the first gate sidewall films (silicon oxide films) 20 can be prevented from being etched in the step of removing a native oxide film which is performed prior to formation of the silicide films. Thus, the second gate sidewall films 31 can be prevented from being lift off. Even in a case where the elevated source/drain process is applied, the gate and the source/drain can be prevented from being shorted by the formed silicon layer, silicon germanium layer or the like.

### Third Embodiment

Next, a semiconductor device including a MOS field effect transistor (MOSFET) according to a third embodiment of the present invention will be explained. Elements of the third embodiment similar to those of the first embodiment are denoted by like or similar reference numbers.

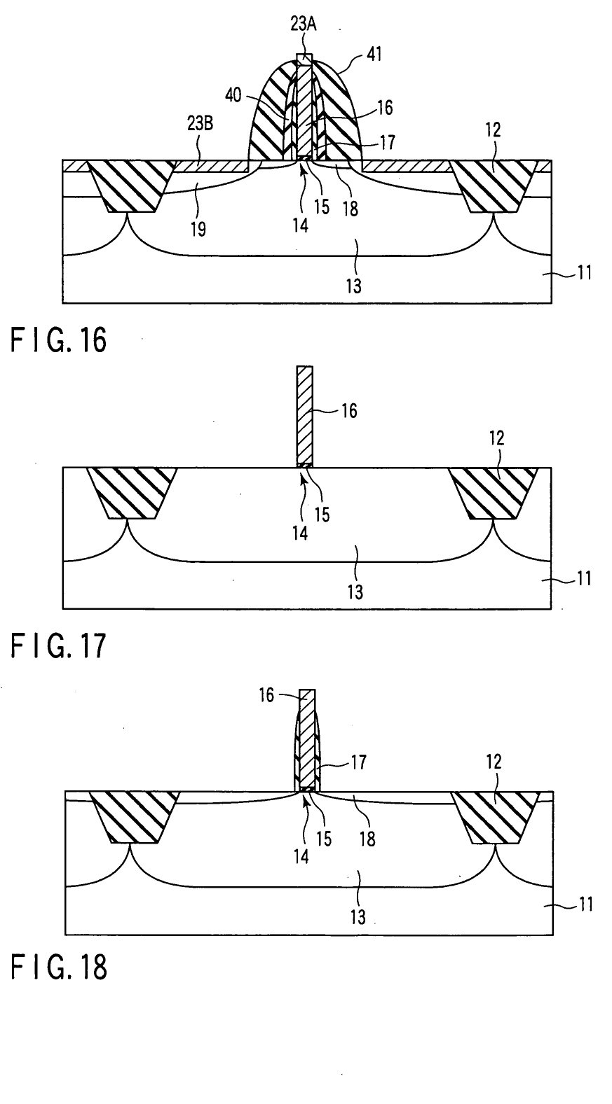

FIG. 16 illustrates a cross-sectional view of the MOSFET according to the third embodiment. Element isolation films 12 are formed on a p-type silicon semiconductor substrate (or an n-type silicon semiconductor substrate) 11. A well region 13 and a channel region 14 are formed on the semiconductor substrate 11 of an active element portion surrounded by the element isolation films 12. A gate insulation film 15 is formed on the semiconductor substrate (channel region) 11 of the active element portion. A gate electrode 16 is formed on the gate insulation film 15.

Offset spacers 17 composed of silicon oxide films are formed on side surfaces of the gate electrode 16. Shallow diffusion layers 18 are formed on the surface region of the semiconductor substrate 11 so as to sandwich the channel region 14. Contact junctions 19 serving as a source region and a drain region are further formed on the surface region of the semiconductor substrate 11 so as to sandwich the shallow diffusion layers 18.

First gate sidewall films 40 composed of silicon oxide films are formed on the offset spacers 17 on the side surfaces of the gate electrode 16. Second gate sidewall films 41 composed of silicon nitride films are formed on the first gate sidewall films 40, and on the side surfaces of the top portion of the fate electrode 16. A silicide film 23A is formed on the top surface of the gate electrode 16 and silicide films 23B are formed on the contact junctions 19. The second gate sidewall films 41 are also formed on the side surfaces of the silicide film 23A located on the top surface of the fate electrode 16.

In the semiconductor device having the above-described structure, for example, as the silicon nitride films formed of a different material from the silicon oxide films are formed on the side surfaces of the top portion of the gate electrode, the side surfaces of the top portion of the gate electrode can be prevented from being exposed during a preprocessing performed prior to formation of the silicide films.

To describe detail, as the second gate sidewall films (silicon nitride films) 41 different from the silicon oxide films are formed on the side surfaces of the silicide film 23A on the gate electrode 16, the side surfaces of the top portion of the gate electrode can be prevented from being exposed during removal of a native oxide film which is performed prior to formation of the silicide films. Thus, the gate electrode can be prevented from being silicified from the side surfaces of the top portion of the gate electrode and the silicide films 23A can be prevented from being formed from the top surface of the gate electrode to deep positions.

In addition, as the first gate sidewall films (silicon oxide films) 40 are formed on the side surfaces of the lower portion of the gate electrode 16, a problem of decrease in reliability of the transistor does not arise. The offset spacers 17 are formed on the side surfaces of the lower portion of the gate electrode 16. However, as the offset spacers 17 are thin, reliability of the transistor cannot be maintained with the offset spacers alone.

Next, a method of producing the MOSFET according to the third embodiment will be explained. FIG. 17 to FIG. 21 illustrate steps in the method of producing the MOSFET.

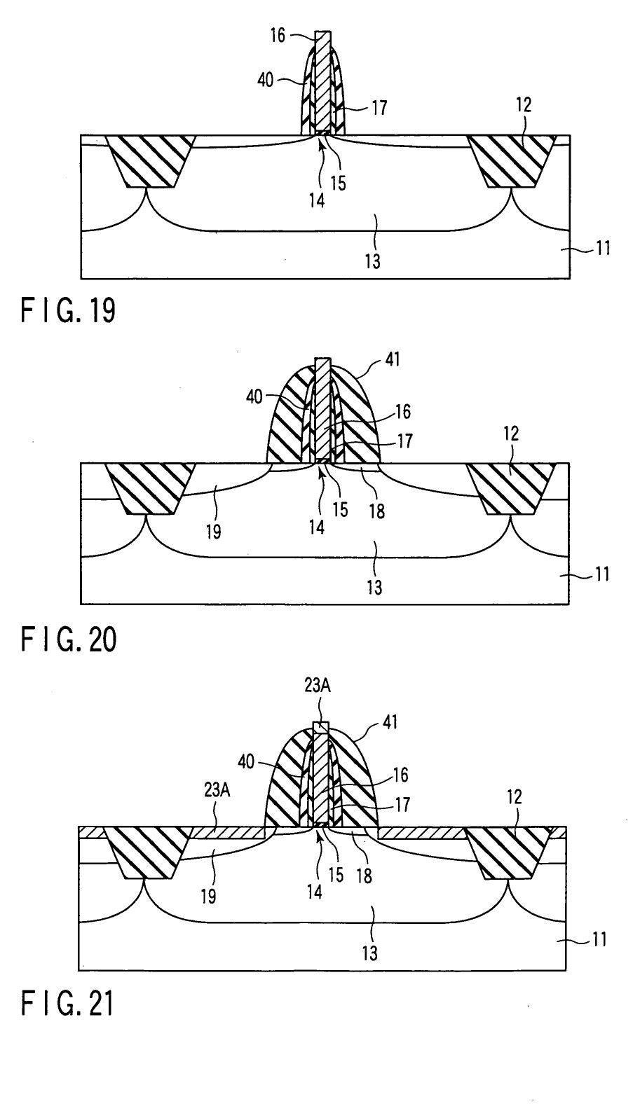

The steps shown in FIGS. 17 and 18 are the same as the steps of the first embodiment shown in FIGS. 5 and 6. Next, a silicon oxide film is deposited on the structure shown in FIG. 18, i.e. on the offset spacers 17 on the side surfaces of the gate electrode 16. The silicon oxide film is subjected to etch back by RIE, such that the first gate sidewall films 40 are formed on the offset spacers 17 on the side surfaces of the gate electrode 16 as shown in FIG. 19. At this time, overetching is slightly performed to certainly perform patterning of these sidewall insulation films. For this reason, the side surfaces of the top portion of the gate electrode 16 are exposed.

Subsequently, a silicon nitride film is deposited on the structure shown in FIG. 19. After that, etch back is performed by RIE, such that the second gate sidewall films 41 are formed on the side surfaces of the top portion of the gate electrode 16, and on the first gate sidewall films 40 on the side surfaces of the gate electrode 16, as shown in FIG. 20. At this time, second gate sidewall films 41 prevent the first gate sidewall films 40 formed of a silicon oxide film from being exposed. Impurities are introduced onto the semiconductor substrate 11 on both sides of the second gate sidewall films 41 by ion implantation and RTA is further performed to form the contact junctions 19 which are to serve as the source region and the drain region.

Next, after diluted hydrofluoric acid processing is performed to remove the native oxide film, in the structure shown in FIG. 20, the silicide film 23A is formed on the gate electrode 16 and the silicide films 23B are formed on the contact junctions 19 (salicide). The silicide films 23A and 23B are formed of, for example, silicides of Ni, Ti, Co, Pb or the like. The salicide of forming nickel silicide films is explained here.

First, a nickel film is deposited on the gate electrode 16 and the contact junctions 19 by spattering. Then, RTA is performed at a temperature of 400 to 500° C. to silicify the nickel film. After that, an unreacted portion of the nickel film is removed with a mixture solution of sulfuric acid and hydrogen peroxide solution, and nickel silicide films 23A and 23B are formed on the gate electrode 16 and the contact junctions 19 as shown in FIG. 21. The other producing steps are the same as those of the first embodiment.

The second gate sidewall films (silicon nitride films) 41 different from silicon oxide films are formed on the side surfaces of the top portion of the gate electrode 16, as shown in FIG. 21, in the above-described producing steps.

Thus, the side surfaces of the top portion of the gate electrode 16 can be prevented from being exposed in the step of removing a native oxide film which is performed prior to formation of the silicide films. The nickel film is not formed on the side surfaces of the top portion of the gate electrode 16 in the step of forming the silicide films. For this reason, silicidation of the gate electrode 16 from the side surfaces of the top portion of the gate electrode 16 can be restricted or, in other words, formation of a nickel silicide film from the side surfaces of the gate electrode 16 can be restricted. The formation of the silicide film from the top surface of the gate electrode 16 to a deep position can be therefore prevented. As the first gate sidewall films (silicon oxide films) 40 are formed on the side surfaces of the lower portion of the gate electrode 16, a problem of decrease in reliability of transistor does not arise.

The embodiments of the present invention can provide a semiconductor device capable of restricting silicidation performed from the side surfaces of the gate electrode, preventing the silicide films from being formed to deep positions inside the gate electrode and maintaining the reliability of transistor, and can also provide a producing method of the semiconductor device.

The above-described embodiments cannot only be accomplished separately, but can be combined in appropriate manners. Furthermore, the embodiments contain various aspects of the invention. Thus, various aspects of the invention can also be extracted from any appropriate combination of a plurality of constituent elements disclosed in the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a gate insulation film formed on a semiconductor substrate;
a gate electrode formed on the gate insulation film;
a silicide film formed on the gate electrode;
first gate sidewall films formed on side surfaces of the gate electrode;
second gate sidewall films formed on the first gate sidewall films on the side surfaces of the gate electrode;
first sidewall films formed on side surfaces of the silicide film on the gate electrode;
a source region and a drain region formed on the semiconductor substrate so as to sandwich a channel region formed under the gate insulation film; and
second sidewall films formed on end portions of the first and second gate sidewall films formed on the source region and the drain region.

2. The semiconductor device according to claim 1, wherein each of the first and second gate sidewall films has an L-shaped cross-section elongated along a gate length of the gate electrode and the first gate sidewall films are covered by the second gate sidewall films, the first sidewall films and the second sidewall films.

3. The semiconductor device according to claim 2, wherein the first gate sidewall films are formed of a silicon oxide film, the second gate sidewall films are formed of a silicon nitride film, and the first and second sidewall films are formed of a silicon nitride film.

4. The semiconductor device according to claim 1, further comprising:
offset spacers formed between the gate electrode and the first gate sidewall films; and
shallow diffusion layers formed between the source region and the drain region by using the offset spacers as mask members, such that the channel region is sandwiched between the shallow diffusion layers.

5. The semiconductor device according to claim 1, wherein each of the first gate sidewall films has an L-shaped cross-section elongated along a gate length of the gate electrode and the first gate sidewall films are covered by the second gate sidewall films, the first sidewall films and the second sidewall films.

6. A semiconductor device comprising:
a gate insulation film formed on a semiconductor substrate;
a gate electrode formed on the gate insulation film;
a silicide film formed on the gate electrode;
first gate sidewall films formed on side surfaces of the gate electrode; and
second gate sidewall films formed on the first gate sidewall films on the side surfaces of the gate electrode, and on side surfaces of the silicide film.

7. The semiconductor device according to claim 6, wherein the first gate sidewall films are formed of a silicon oxide film and the second gate sidewall films are formed of a silicon nitride film.

8. The semiconductor device according to claim 6, further comprising:
offset spacers formed between the gate electrode and the first gate sidewall films;
shallow diffusion layers formed on the semiconductor substrate by using the offset spacers as mask members, the shallow diffusion layers sandwiching a channel region formed under the gate insulation film; and
a source region and a drain region formed on the semiconductor substrate, the source region and the drain region sandwiching the shallow diffusion layers.

9. A method of producing a semiconductor device, comprising:
forming a gate insulation film on a semiconductor substrate;
forming a gate electrode on the gate insulation film;
forming first gate sidewall films on side surfaces of the gate electrode and on the semiconductor substrate;
forming second gate sidewall films on the first gate sidewall films;
forming third gate sidewall films on the second gate sidewall films;
forming first sidewall films on side surfaces of a top portion of the gate electrode, and on end portions of the first and second gate sidewall films on the semiconductor substrate;
forming a source region and a drain region on the semiconductor substrate on both sides of the third gate sidewall films by ion implantation using the third gate sidewall films as mask members;
removing a native oxide film on the gate electrode, the source region and the drain region;
forming a metal film on the gate electrode, the source region and the drain region; and
performing heat treatment on the gate electrode, the source region and the drain region, and the metal film, to form metal silicide films on the gate electrode, the source region and the drain region.

10. A method of producing a semiconductor device, comprising:
forming a gate insulation film on a semiconductor substrate;
forming a gate electrode on the gate insulation film;
forming first gate sidewall films on side surfaces of a lower portion of the gate electrode;
forming second gate sidewall films on side surfaces of an upper portion of the gate electrode and on the first gate sidewall films;
forming a source region and a drain region on the semiconductor substrate on both sides of the second gate sidewall films by ion implantation using the second gate sidewall films as mask members;
removing a native oxide film on the gate electrode, the source region and the drain region;
forming a metal film on the gate electrode, the source region and the drain region; and
performing heat treatment on the gate electrode, the source region and the drain region, and the metal film, to form metal silicide films on the gate electrode, the source region and the drain region.
